(19) United States
(12) Patent Application Publication
(10) Pub. No.: US 2012/0229977 A1
(43) Pub. Date: Sep. 13, 2012

(54) Coaxial Capacitor Bus Termination

(75) Inventors: Terry Hosking, Barre, VT (US); Michael Brubaker, Loveland, CO (US)

(73) Assignee: S B E, INC., Barre, VT (US)

(21) Appl. No.: 13/416,900

(22) Filed: Mar. 9, 2012

Related U.S. Application Data
(60) Provisional application No. 61/451,665, filed on Mar. 11, 2011.

(51) Int. Cl. H05K 7/20; H03H 7/00

(52) U.S. Cl. 361/688; 333/181

(57) ABSTRACT

Parallel plate bus structures are commonly used for high-current applications where low inductance is a requirement. Such bus structures are very well suited for inverter topologies used to convert from DC to AC power and a capacitor is needed to minimize ripple on the DC bus. However, such arrangements are not able to provide sufficiently low inductance to easily eliminate bypass capacitors which typically requires a system inductance below 10 nH nor do they provide any natural EMI suppression. The present invention utilizes that natural circular symmetry of a circular film capacitor winding by implementing a coaxial shaped bus connection from the capacitor to the switching semiconductors in the DC bus application of DC to AC inverter. The result is an achievement of lower ESL and geometry based EMI suppression without the use of external-lumped filtering components.

This application is a non-provisional of U.S. provisional application 61/451,665 “Coaxial Capacitor Bus Termination” filed Mar. 11, 2011. This application claims all priority and benefit of the preceding provisional application.

### FIELD OF THE INVENTION

The present invention relates to the use of a wound polymer film capacitor with positive and negative plate connection terminals forming a circular plurality of connection legs to a common surface plane above the capacitor and then connecting the resulting legs to a similarly configured switching system in such a way as to maintain the connection symmetry initiated by the circular capacitor winding. Connections may be numerous but must be symmetric. The result is a balanced impedance of the system. Very low inductance (typically less than 10 n) and geometry based EMI suppression through shielding effect by magnetic field cancellation. Such effects are increased as switching frequency is increased.

### DESCRIPTION OF PRIOR ART

A two conductor transmission line can be readily designed to provide symmetry, near zero field emission, low resistance, and very low inductance. However, incorporating external circuit elements such as a capacitor into the line typically perturbs the design and reduces performance. This problem is further compounded for DC link applications where high currents are present such that cooling of the capacitor and bus structure is required.

Innovative connections have been used to make low inductance connections to switch mechanisms.

Schimanek teaches in U.S. Pat. No. 6,262,876 of bringing connections through the center hole of a capacitor to provide low inductance connection to a 2 plate bus structure. This is actually known art in its basic form and while providing better connection than prior art, it does not retain impedance symmetry and does not provide the lowest connection inductance to a properly orientated switch system. External connections around the outside of the capacitors involved are superior to this method.

Richardon teaches in U.S. Pat. No. 6,396,332 of locating box type capacitors strategically surrounding a switch and connecting each box symmetrically to the switch to lower inductance and provide system symmetry. However, in the teachings, there is no symmetry of the capacitor itself and the capacitors do not drive the system efficiency. They are placed around it. The end result is improvement but not optimization.

Arbanas teaches in U.S. Pat. No. 6,278,603 of locating a ring of conducting material around the outside of a capacitor and a rod down the center to make a low inductance connection to a planar bus structure. While this connection is an improvement to pervious art connections to a rectangular switch bus structure, there is no attempt to carry the symmetry of the circular capacitor section to the switch itself through symmetric connections.

Hosking teaches in U.S. Pat. No. 7,289,311 of utilizing the low inductance connections afforded by placing switches and loads in the center of a capacitor of sufficient size that a center hole can be made as to place such items inside the hole. However, in the invention stated here, the coaxial connection carries the benefits of Hosking's teachings outside the hole to a parallel switching structure that is no longer the in the hole, but receives the same benefits.

### DESCRIPTION OF DRAWINGS

FIG. 1 shows the basic concepts of a coaxial bus structure.

FIG. 2 shows a concept embodiment where the capacitor is used as the DC link for a high performance multiphase inverter.

FIG. 3 shows the basic concepts where the coaxial bus structure contains more than 2 coaxial conductors.

### SUMMARY OF PRESENT INVENTION

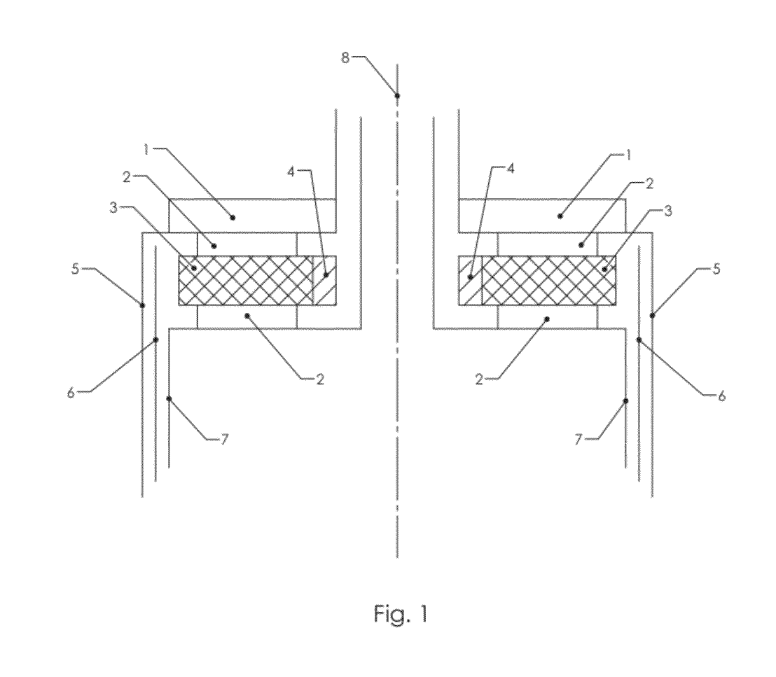

What is presented is a circular (coaxial) bus structure integrated with a wound film capacitor (FIG. 1). The axis of the annular capacitor (8) is the same as the axis of both conductors in the coaxial bus structure (5,7). The conductors are separated by coaxial insulation (6). The coaxial bus structure provides the lowest possible inductance with perfect cancellation of the magnetic fields and the best use of the conductor cross section for high frequency current since there are no edges. A capacitor (3) with a sufficiently large hollow core (4) can be incorporated into the coaxial bus structure while preserving the cylindrical symmetry as shown. The size of such core is not specifically critical but there is a requirement that a manufacturable embodiment allows conductors (for this illustration, 5,7) to pass through the hole. The capacitor is electromechanically connected to the bus structure via an interface (3) as taught by Hosking (U.S. Pat. No. 7,453,114). This geometry can be utilized to provide a matching impedance for pulsed power systems or lower frequency filtering applications. In either case, an external cooling plate (1) can be incorporated into the coaxial bus structure with no cost in electrical performance. The cooling plate allows control of the bus temperature and capacitor winding hotspot temperature as required. The integration of bus, capacitor, and cooling provides for reduced cost, weight, and space in the end application. It is assumed that if liquid cooling is used to cool this plate (3) that the cooling fluid or the cooling plate is galvanically isolated from the coaxial conductors.

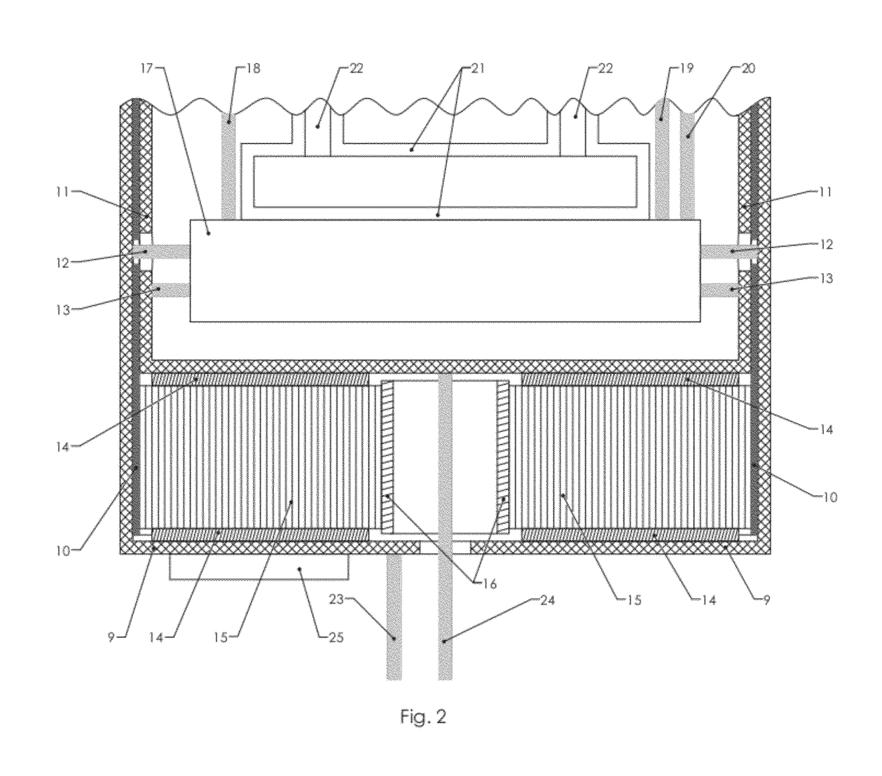

The advantages of this coaxial capacitor/bus combination are as follows:
1) The concept drawing in FIG. 2 does not show the necessary inductive filtering required to remove the switching frequency [and its harmonics] from the output. The switching harmonics must be kept out of the DC bus to prevent Electro-Magnetic Interference [EMI] radiating from the conductors. The extremely low inductance between the capacitor and DC bus connections results in dramatic attenuation of the undesired switching noise on the DC bus. In addition, the low inductance between the capacitor and coaxial bus structure minimizes voltage overshoot on the switches [L*dI/dt] when they turn off. This allows lower voltage switches to be used, with their lower on state conduction losses. It also eliminates the need for separate snubber/bypass capacitors located at the DC input terminals of the switches.

2) As previously described, the coaxial nature of the bus orientation contains the magnetic field

3) between the inner and outer coaxial conductors. This allows placement of low power control and switch drive electronics within the center of the structure with minimum possible switch transient induced noise on circuit board traces.

4) Since the switch loss heat flux is so high, liquid coolant thermal management systems must be used. This construction does not interfere with the coolant plumbing required. This configuration also allows heat removal from the coaxial bus without the need for it to be within the coaxial space. One could conceive a heat pipe to be used to move heat from the inner bus conductor, with the heat pipe emerging from the capacitor core parallel to the DC input conductors.

5) Although not an optimal solution, there are times where a rectangular structure must be used to make best use of available space. The same inner and outer conductor geometry would be advantageous. For this case an essentially rectangular capacitor structure must be implemented such that current flow is in the same direction as shown in FIG. 2. There are several known art methods for accomplishing this.

These concepts can be expanded to include structures with more than 2 conductive cylinders, including more than 1 capacitor such that such a structure could be used for other purposes such as but not limited to an “n-phase filter” to remove switching noise from the output of a multi-phase inverter.

### DESCRIPTION OF A PREFERRED EMBODIMENT

The concept of the present invention can be expanded to include an “n-phase inverter”, or any DC to DC converter link capacitor. FIG. 2 illustrates (via cross section view) a 3 phase DC to AC power inverter showing an advantageous embodiment of a coaxial capacitor and bus structure. The coaxial structure consists of two hollow conductive cylinders (9,11) separated by an insulating cylinder (10). The capacitor winding (15) and its core (16) are sandwiched between the conductive ends of the conductive cylinders (9,11). The capacitor winding (15) is electromechanically attached to the conductive ends of the conductive cylinders (9,11) via a conductive interface (14), the necessary details of this interface (14) are taught by Hosking (U.S. Pat. No. 7,453,114). Within the conductive cylinders (9,11) is mounted semiconductor switch module (17) which through a plurality of connections (12,13) takes DC power from the coaxial bus structure (9,10,11). The DC power is supplied to the coaxial bus structure through connections (23,24) near the axial center of the coaxial bus structure. One connection (24) must pass through the outer hollow conductive cylinder (9) to access the inner cylinder (11). The three phase inverter output is illustrated via conductors (18,19,20) near the top of FIG. 2. Thermal management of the semiconductor switch module is illustrated via a liquid cooled plate (21) with coolant inlet/outlets (22). Cooling the coaxial bus structure and the capacitor can be done externally via another thermal management device (25) the location of which can be anywhere outside the outer hollow conductive cylinder (9) that is mechanically and thermally advantageous without having any effect on the electrical performance of the entire assembly. It must be noted that this thermal management device (25) or its coolant must be galvanically isolated from the outer hollow conductive cylinder (9).

### Description of another useful Embodiment

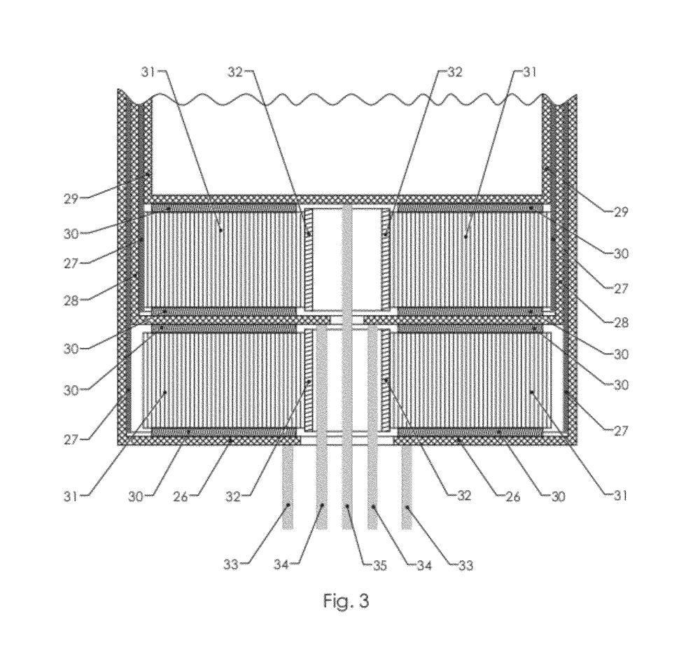

The concept of the present invention can also be expanded to include more than 2 conductive hollow cylinders. Refer to FIG. 3 for a concept drawing of a filter that would be useful for removing high frequency energy from the output of a DC to AC inverter. There are 3 hollow cylindrical conductors(outer: 26, center: 28, inner: 29) separated by insulation (27). Unfiltered AC would be applied to the three conductive hollow cylinders (26,28,29). The undesired high frequency energy would be blocked by the two capacitors (31) sandwiched between the 3 conductive cylinders (26,28,29). The capacitor windings (31) are electromechanically attached to the conductive ends of the conductive cylinders (26,28,29) via conductive interfaces (30), the necessary details of this interface (30) are taught by Hosking (U.S. Pat. No. 7,453,114). The output of this filter apparatus (33,34,35) would be routed through the cores (32) of the capacitors (31) and would be free of the undesired high frequency energy.

Note that more than 3 conductive cylinders could be arranged into such a coaxial bus structure if it was advantageous to do so, such as for a n-phase filter where the capacitance between each of the n-phases would ideally be the same. Note also that the capacitors used in such systems do not all need to be identical in form or in value.

### REFERENCED PATENTS

Schimanek—U.S. Pat. No. 6,262,876

Richardon—U.S. Pat. No. 6,396,332

Arbanas—U.S. Pat. No. 6,278,603

Hosking—U.S. Pat. No. 7,289,311

Hosking—U.S. Pat. No. 7,453,114

1. I claim everything here noted.

2. A low-inductance, low-resistance, and near zero field emission coaxial bus structure with an integrated wound film capacitor to be used for, but not limited to, impedance matching or filtering. This includes bus structures with more than two coaxial conductors.

3. A means of externally cooling a wound capacitor and bus structure as required without perturbing the electro-magnetic performance of the system.

4. An efficient means of ripple current filtering in a DC link with the best possible utilization of the bus conductor cross section. The connection between the capacitor and DC source has no sharp edges or corners such that the skin effect only acts in the radial direction.

5. A packaging method for a single, three-phase, or n-phase inverter which provides the lowest possible inductance between the integrated annular capacitor and switch modules along with total containment of the electromagnetic fields.

6. All of the embodiments described in the preceding claims as applied to a coaxial structure of non-circular (e.g. square, rectangular, elliptical, etc.) cross section.

7. All of the embodiments described in claim 6 where the axis of the inner and outer conductor are not the same.
